(19) United States
(12) Patent Application Publication
(10) Pub. No.: US 2013/0014821 A1
(43) Pub. Date: Jan. 17, 2013

(54) PHOTOVOLTAIC MODULE

(71) Applicants: Stephen Yau-Sang CHENG, Hong Kong (HK); Chui-Ling Yip, Hong Kong (HK)

(72) Inventors: Stephen Yau-Sang CHENG, Hong Kong (HK); Chui-Ling Yip, Hong Kong (HK)

(73) Assignee: Du Pont Apollo Limited, Hong Kong (HK)

(21) Appl. No.: 13/182,447

(22) Filed: Jul. 14, 2011

(51) Int. Cl. H01L 31/0203

(52) U.S. Cl. 136/259

(57) ABSTRACT

Disclosed herein is a photovoltaic module, which includes a photovoltaic member, a moisture-resistant layer, a mounting frame covering and a buffer layer. The buffer layer disposed between the moisture-resistant layer and the mounting frame, where the buffer layer is made of a material selected from the group consisting of polypropylene-based polymer, polyethylene-based polymer, polyurethane-based polymer, ethylene-vinyl acetate-based resin and a combination thereof.

### BACKGROUND

1. Field of Invention

The present disclosure relates to a photovoltaic module.

2. Description of Related Art

Photovoltaic (PV) modules are units capable of converting radiant energy, the energy of the sun, into electrical energy with the aid of photovoltaic cells. Conventional photovoltaic modules (PV modules) are typically in laminated structures, which including at least a photovoltaic cell, a front transparent substrate and a back protective substrate. Typically, a plurality of photovoltaic cells can be connected to form a photovoltaic cell string, and the photovoltaic cell strings are usually encapsulated between the front transparent substrate and the back substrate. The front and back substrates of the PV module are usually provided for environmental and structural protection and weather resistance to the photovoltaic cells. Generally, PV module also comprises a rigid mounting frame so as to, support the PV member and to provide attachment points for securing the solar module to the installation site. Moreover, the conventional gasket is rigid, which requires a pre-fabrication process or molding process in order to fit the certain size or shape of the mounting frame. The pre-fabrication process of producing gasket is time-consuming and costly in the convention design of the modules. Accordingly, there exists in this art a need of improved photovoltaic modules that are free of the aforementioned problems.

### SUMMARY

The following presents a summary of the disclosure in order to provide a basic understanding to the reader. This summary is not an extensive overview of the disclosure and it does not identify key/critical elements of the present disclosure or delineate the scope of the present disclosure. Its sole purpose is to present some concepts disclosed herein in a simplified form as a prelude to the more detailed description that is presented later.

In one aspect, the present disclosure is directed to a photovoltaic module. The photovoltaic module comprises a photovoltaic member having a side edge; a moisture-resistant layer adhered to the side edge of the photovoltaic member; a mounting frame covering the moisture-resistant layer; and a buffer layer disposed between the moisture-resistant layer and the mounting frame, wherein the buffer layer is made of a material selected from the group consisting of polypropylene-based polymer, polyethylene-based polymer, polyurethane-based polymer, ethylene-vinyl acetate-based resin and a combination thereof.

According to one embodiment of the present disclosure, the buffer layer is in contact with the moisture-resistant layer. In one embodiment, the buffer layer has a foam structure with a bulk density of about 0.05 g/cm³ to about 0.6 g/cm³.

According to one embodiment of the present disclosure, the mounting frame comprises a body, a first portion and a second portion. The first and second portions respectively extend from two opposite ends of the body.

In one embodiment, the first portion extends to a position above the photovoltaic member, whereas the second portion extends to a position below the photovoltaic member. In another embodiment, the photovoltaic module further comprises a first sealant and a second sealant. The first sealant is disposed between the first portion and the photovoltaic member. The second sealant is disposed between the second portion and the photovoltaic member. The first and second sealants may be made of silicone, for example.

According to one embodiment of the present disclosure, the moisture-resistant layer has a thickness of at least 0.5 mm. In embodiments, the moisture-resistant layer may be made of butyl rubber, silicone or polyurethane.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view schematically illustrating a photovoltaic module according to one embodiment of the present disclosure; and

FIG. 2 is a graph of accumulative power change vs. exposure time period for the highly accelerated stress tests of the photovoltaic modules.

### DETAILED DESCRIPTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

References in the singular may also include the plural (for example, “a” and “an” may refer to one, or one or more) unless the context specifically states otherwise. The use of numerical values in the various ranges specified in this application, unless expressly indicated otherwise, are stated as approximations as though the minimum and maximum values within the stated ranges were both preceded by the word “about”. In this manner, slight variations above and below the stated ranges can be used to achieve substantially the same results as values within the ranges. Also, the disclosure of these ranges is intended as a continuous range including every value between the minimum and maximum values.

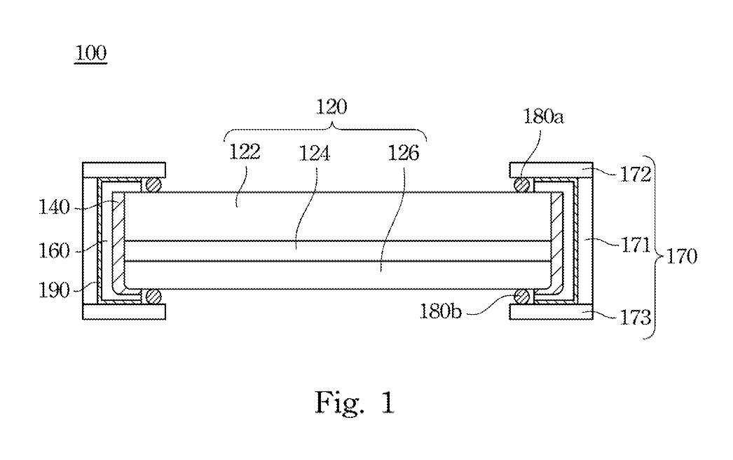

FIG. 1 is a cross-sectional view schematically illustrating a photovoltaic module 100 according to one embodiment of the present disclosure. The photovoltaic module 100 comprises a photovoltaic member 120, a moisture-resistant layer 140, a buffer layer 160 and a mounting frame 170. The moisture-resistant layer 140 is adhered to the side edge of the photovoltaic member 120. The moisture-resistant layer 140 is covered by the mounting frame 170. The buffer layer 160 is disposed between the moisture-resistant layer 140 and the mounting frame 170.

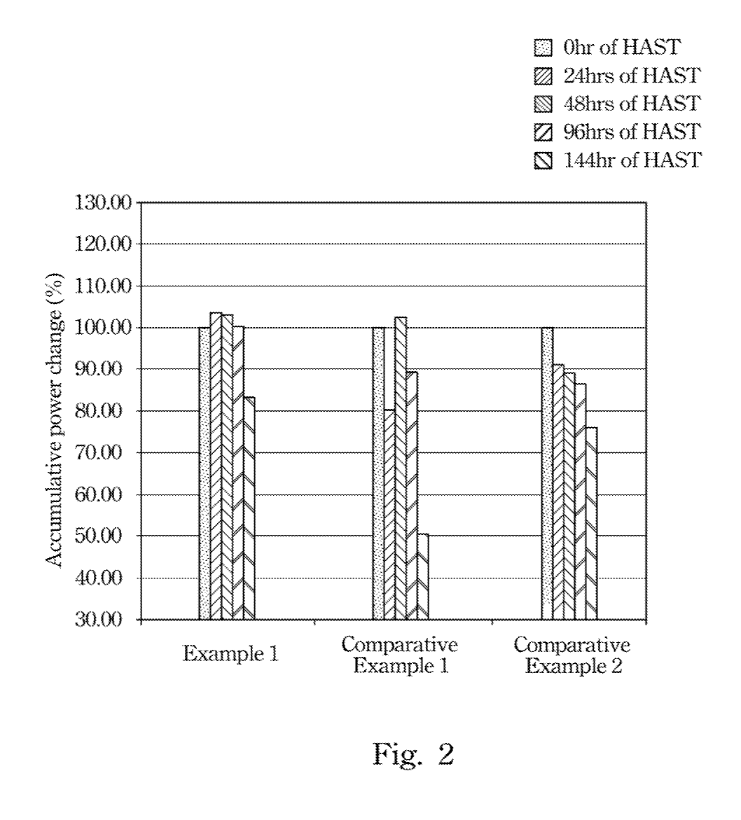

The photovoltaic member 120 may comprises a front substrate 122, an encapsulant 124, at least one photovoltaic cell (not depicted in FIG. 1 and FIG. 2) and a back substrate 126. The front substrate 122 is usually transparent, and thus allowing the light to pass therethrough before being absorbed by the photovoltaic cell. The material of the front substrate 122 typically is a light-transmitting material, such as but not limited to a glass plate or a polymeric film. The encapsulant 124 used herein is for protecting the photovoltaic cell from the weather agent, such as humidity, moisture, water or water vapor. For example, the encapsulant 124 may be made from polymeric material such as ethylene/vinyl acetate copolymer (EVA) or polyvinyl butyral (PVB). The primary functions of the back substrate 126 are for electrical insulation, mechanical support and protection, and weathering resistance. The back substrate 126 is often a multi-layered laminate sheet, such as a backsheet. In embodiments, the backsheet could be but not limited to PV backsheet PR303 (trade name) provided by SFC Co. LTD, Korea or Toyal Solar® provided by Toyo Aluminium KK, Japan. Besides, it is appreciated that the PV module 100 may comprise additional components such as a junction box and other structural parts. However, for the sake of clarity, those components are omitted in the diagram provided herein.

The moisture-resistant layer 140 is adhered to the side edge of the photovoltaic member 120. Generally, the moisture-resistant layer 140 is further extended to the bottom surface of back substrate 126. The side edges of the photovoltaic member 120 can be fully sealed with the moisture-resistant layer 140. The moisture-resistant layer 140 is operable to prevent moisture or mist from penetrating into the photovoltaic cells though the interface between the front substrate 122 and the encapsulant 124, or through the interface between back substrate 126 and the encapsulant 124. Accordingly, the moisture-resistant layer 140 may improve the reliability of the photovoltaic module 100. In one embodiment, the moisture-resistant layer 140 has a thickness of at least 0.5 mm to ensure the moisture resistance ability. The moisture-resistant layer 140 may comprise at least one of butyl rubber, silicone and polyurethane. For example, the moisture-resistant layer 140 could be but not limited to M155 (trade name) provided from Yokohama Rubber Co., Ltd, Japan.

The buffer layer 160 is disposed between the moisture-resistant layer 140 and the mounting frame 170. The buffer layer 160 is function as a shock absorber to protect the edge of the photovoltaic member 120 from being fractured or broken. In one embodiment, the buffer layer is in contact with the moisture-resistant layer 140. In another embodiment, the buffer layer 160 could also be extended to the top or the bottom surface of the photovoltaic member 120. The buffer layer 160 could be one layer or multiple layers. In still another embodiment, the buffer layer 160 is in a foam structure. For example, the buffer layer 160 could be a foam tape, a foam cloth or a combination thereof. In yet another embodiment, the foam structure of the buffer layer 160 has a bulk density of about 0.05 g/cm³ to about 0.6 g/cm³.

Besides, suitable buffer layer 160 materials should be selected in order to avoid the chemical interaction between the moisture-resistant layer 140 and the buffer layer 160. Accordingly, the buffer layer 160 is made of a material such as polypropylene-based polymer, polyethylene-based polymer, polyurethane-based polymer, ethylene-vinyl acetate-based resin or a combination thereof.

Optionally, the photovoltaic module 100 may further comprise an adhesive layer 190 disposed between the mounting frame 170 and the moisture-resistant layer 140, and thus allowing the buffer layer 160 to be adhesively attached to the mounting frame 170 or the moisture-resistant layer 140. Accordingly, the adhesive layer 190 may be disposed between the buffer layer 160 and the mounting frame 170 or/and between the buffer layer 160 and the moisture-resistant layer 140. Particularly, the adhesive layer 190 could be adhesive taps or the adhesive materials enabling the buffer layer 160 to be adhesively attached.

The mounting frame 170 provided herein is to protect the side edge of photovoltaic member 120. Furthermore, the mounting frame 170 protects the photovoltaic member 120 from mechanical load or impacts. The mounting frame 170 covers the moisture-resistant layer 140 and the buffer layer 160. In one embodiment, the mounting frame 170 comprises a body 171, a first portion 172 and a second portion 173. The body 171 covers the moisture-resistant layer 140, and the first portion 172 and second portion 173 extend from two opposite ends of the body 171 respectively. In another embodiment, the first portion 172 extends to a position above the photovoltaic member 120. In yet another embodiment, the second portion 173 extends to a position below the photovoltaic member 120. Accordingly, the mounting frame 170 covers a portion of bottom or/and top surface of the photovoltaic member 120.

Since the mounting frame 170 is operable to protect the photovoltaic member 120, the mounting frame 170 is made of the material that could support enough load or weight. In some embodiments, the mounting frame 170 can be a metal frame or a plastic frame. Specifically, the metal mounting frame 170 may include aluminum, stainless steel, or a metal coated with an anti-corrosive layer. The plastic mounting frame 170 may include polyphenylene oxide (PPO) or polyphenylene ether (PPE).

In one embodiment, the photovoltaic module 100 further comprises a first sealant 180a and a second sealant 180b. The first sealant 180a is disposed between the first portion 172 of the mounting frame 170 and the photovoltaic member 120. The second sealant 180b is disposed between the second portion 173 of the mounting frame 170 and the photovoltaic member 120. The first sealant 180a and the second sealant 180b are used to prevent water or water vapor from migrating into the photovoltaic member 120 through the gaps existing between the mounting frame 170 and the top/bottom surfaces of the photovoltaic member 120, and thus to provide a better reliability of the photovoltaic module 100. In some embodiments, the first sealant 180a and the second sealant 180b are made of silicone, for the reason that silicone provides as a good barrier for moisture/water vapor prevention. For example, the first sealant 180a and the second sealant 180b could be a room-temperature-curing-type silicone sealant. The first sealant 180a and the second sealant 180b could also be a silicone paste or a silicone gel made form a single product or a mixed product. In some embodiments, the silicone sealant enables to withstand a temperature of −40 to 90° C. For example, silicone could be but not limited to KE45 (trade name) provided by ShinEtsu Chemical Co., Ltd, Japan, PV8301 (trade name) provided by Dow Corning Silicones, United States, 8303 (trade name) provided by Dow Corning Silicones, United States, PV804 (trade name) provided by Dow Corning Silicones, United States, TS1527 (trade name) provided by Beijing TONSAN Adhesive Co, Ltd, China, TS1521 (trade name) provided by Beijing TONSAN Adhesive Co, Ltd, China, 382 (trade name) provided by Momentive, United States, Goloho-63 (trade name) provided by Goloho, China.

In another embodiment, the photovoltaic module 100 may further comprise a desiccant. The desiccant can be positioned between the mounting frame 170 and the moisture-resistant layer 140. Specifically, the desiccant can be placed in the position between the moisture-resistant layer 140 and the buffer layer 160, or between the buffer layer 160 and the adhesive layer 190. In some embodiments, the desiccant is made from the material that can be mixed with or can be grafted to the polymer chains of the moisture-resistant layer 140 or the buffer layer 160. The desiccant may comprise the material including molecular sieves, zeolite, dehydrated clays and silicates. Furthermore, the desiccant can also be a material that chemically reacts with water, such as inorganic or organic anhydrides or anhydrous compounds.

### Highly Accelerated Stress Test

The highly accelerated stress tests (HAST) have been conducted to exam the reliability of the exemplary embodiment of the present disclosure (Example 1) and other modules (Comparative examples 1-2). The photovoltaic members of all examples are prepared with backsheets. The encapsulants of all photovoltaic members are made from EVA, where EVA of Example 1 is provided from Texyear Industries INC, and EVA of Comparative example 2 are provided from MITSUI & Co., LTD. The moisture-resistant layer of all examples includes butyl rubber and M155 (Yokohama Rubber Co., Ltd, Japan). The white foam is applied as the buffer layer in Example 1, whereas gaskets (Jian Dong Rubber Product CO., LTD) are applied in Comparative example 1 and Comparative example 2. The desiccants are applied in between the moisture-resistant layer and the aluminum mounting frame in all examples. The first and the second sealant are offered in Example 1 and Comparative example 1, but Comparative example 2 is provided without the first and the second sealant. The mounting frame of all example are all made of aluminum, where the mounting frame of Example 1 and Comparative example 1 are offered without weep hole, but Comparative example 2 are offered with normal size weep hole. The key elements of Example 1 and the Comparative examples 1-2 are summarized in Table 1.

All photovoltaic modules were placed into an environment at a temperature of 120° C., a relative humidity (RH) of 85%, and an absolute pressure of 0.7 atm for 144 hours, and the photoelectric performance of the modules were measured at 0, 24, 48, 96, 144 hour respectively.

TABLE 1

| | | First and | | |
|---|---|---|---|---|
| | | second | | |
| | Buffer Layer | sealant | Weep holes | Desiccant |
| Example 1 | white foam | silicon | No | Yes |
| Comparative | gasket | silicon | No | Yes |
| example 1 | | | | |
| Comparative | gasket | No | Normal | No |
| example 2 | | | | |

The HAST results of the photovoltaic modules are presented in FIG. 2. As the result shown in FIG. 2, it is observed that Comparative examples 1-2 are technically impossible, since the power of the photovoltaic modules drops gradually as increasing the exposure time. The comparative example 1 shows only about 50% of accumulative power after 144 hours of exposure time. A better photoelectric performance of the module of Example 1 is observed, and the module presents 100% of accumulative power at least after 95 hours of exposure time period, and only slightly drops after 144 hours.

### Loading Test

The photovoltaic module (Example 1) was tested by a standard approach of IEC 61646. According to the test result, the module of Example 1 could withstand 2400 Pa loading, which indicates that the photovoltaic module disclosed herein could withstand wind snow, static or ice loads.

The photovoltaic modules disclosed herein present a better moisture barrier and more cost-effective modules. According to the embodiments disclosed in the present disclosure, the buffer layer is made of a suitable material that is inactive with the moisture-resistant layer, so that the reliability of the photovoltaic module may be improved. Furthermore, the buffer layer used herein could be assembled with the mounting frame without additional pre-fabrication process. Therefore, the photovoltaic module disclosed herein is more cost-effective and has a better reliability.

It will be apparent to those skilled in the art that various modifications and variations can be made to the structure of the present disclosure without departing from the scope or spirit of the invention. In view of the foregoing, it is intended that the present disclosure cover modifications and variations of this invention provided they fall within the scope of the following claims.

What is claimed is:

1. A photovoltaic module, comprising:
a photovoltaic member having a side edge;
a moisture-resistant layer adhered to the side edge;
a mounting frame covering the moisture-resistant layer; and
a buffer layer disposed between the moisture-resistant layer and the mounting frame, wherein the buffer layer is made of a material selected from the group consisting of polypropylene-based polymer, polyethylene-based polymer, polyurethane-based polymer, ethylene-vinyl acetate-based resin and a combination thereof.

2. The photovoltaic module according to claim 1, wherein the buffer layer is in contact with the moisture-resistant layer.

3. The photovoltaic module according to claim 1, wherein the moisture-resistant layer is made of butyl rubber, silicone or polyurethane.

4. The photovoltaic module according to claim 1, wherein the moisture-resistant layer has thickness of at least 0.5 mm.

5. The photovoltaic module according to claim 1, wherein the buffer layer has a foam structure.

6. The photovoltaic module according to claim 1, wherein the buffer layer has a bulk density of about 0.05 g/cm³ to about 0.6 g/cm³.

7. The photovoltaic module according to claim 1, wherein the mounting frame comprises a body, a first portion and a second portion, and the first and second portions respectively extend from two opposite ends of the body.

8. The photovoltaic module according to claim 7, wherein the first portion extends to a position above the photovoltaic member.

9. The photovoltaic module according to claim 8, further comprising a first sealant disposed between the first portion and the photovoltaic member.

10. The photovoltaic module according to claim 9, wherein the first sealant is made of silicone.

11. The photovoltaic module according to claim 7, wherein the second portions extends to a position below the photovoltaic member.

12. The photovoltaic module according to claim 11, further comprising a second sealant disposed between the second portion and the photovoltaic member.

13. The photovoltaic module according to claim 12, wherein the first sealant is made of silicone.

14. The photovoltaic module according to claim 1, wherein the mounting frame is made of metal or plastic.

15. The photovoltaic module according to claim 14, wherein the metal is aluminum, stainless steel.

16. The photovoltaic module according to claim 14, wherein the mounting frame is made of a metal coated with an anti-corrosive layer.

17. The photovoltaic module according to claim 14, wherein the plastic is polyphenylene oxide (PPO) or polyphenylene ether (PPE).

18. The photovoltaic module according to claim 1, further comprising an adhesive layer positioned between the mounting frame and the moisture-resistant layer.

19. The photovoltaic module according to claim 1, further comprising a desiccant positioned between the mounting frame and the moisture-resistant layer.

20. The photovoltaic module according to claim 1, further comprising a desiccant presented in the buffer layer.
